(19) United States
(12) Patent Application Publication
(10) Pub. No.: US 2006/0033175 A1
(43) Pub. Date: Feb. 16, 2006

(54) Load lock modules and semiconductor manufacturing apparatuses

(76) Inventor: Yong-Dae Kim, Suwon-si (KR)

Correspondence Address: HARNESS, DICKEY & PIERCE, P.L.C., P.O. BOX 8910, RESTON, VA, 20195, US

(21) Appl. No.: 11/201,420

(22) Filed: Aug. 11, 2005

(30) Foreign Application Priority Data
Aug. 16, 2004 (KR) 2004-64404

(51) Int. Cl. H01L 31/0232

(52) U.S. Cl. 257/437

(57) ABSTRACT

A load lock module may include a chamber adapted to receive at least one wafer, a supply tube adapted to supply purging gas into the chamber, an outlet adapted to remove the purging gas from the chamber, and an ejector adapted to provide the purging gas to the surface of the at least one wafer received by the chamber.

### PRIORITY STATEMENT

This U.S. non-provisional patent application claims priority under 35 U.S.C. § 119 of Korean Patent Application 2004-64404 filed on Aug. 16, 2004, the entire contents of which are hereby incorporated by reference.

### BACKGROUND

1. FIELD OF THE INVENTION

Example embodiments of the present invention relate to load lock modules and semiconductor manufacturing apparatuses.

2. DESCRIPTION OF THE CONVENTIONAL ART

A conventional etching apparatus may include a load lock module positioned between a process module and an equipment front end module (EFEM). In operation, after an etching process is performed by the process module, a wafer is transferred to the EFEM by the load lock module. When the wafer is transferred, reactive gases sticking to the wafer may flow into the EFEM, for example, simultaneously, which may result in corrosive gases (e.g., HBr, Cl₂, etc.) to flow into the load lock module. For example, gas fumes arising from the wafer may react with moisture in the atmosphere, which may generate by-products, which corrode, for example, a switch (e.g., silicon unilateral switch (SUS)), and degrade operational probability of the equipment.

For example, in selectively etching Si₃N₄, adhered to a wafer by HBr and Cl₂ gas, the chemical formula between them is
Si₃N₄+Cl₂+HBr->SiCl₄+by-product.

In this example, an acid NH₄Cl, which absorbs moisture from the atmosphere and dissolves by itself, is generated as the by-product. The NH₄Cl may be solidified by reacting moisture of the atmosphere, which may corrode the SUS.

### SUMMARY OF THE INVENTION

Example embodiments of the present invention provide load lock modules and semiconductor manufacturing apparatuses, which may more effectively suppress wafer fumes.

An example embodiment of the present invention provides a load lock module, which may include a chamber, a supply tube, an outlet, and an ejector. The chamber may be adapted to receive at least one wafer, and the supply tube may be adapted to supply purging gas into the chamber. The outlet may be adapted to remove the purging gas from the chamber, and an ejector may be adapted to provide the purging gas, supplied through the supply tube, to the surface of the at least one wafer received by the chamber.

Another example embodiment of the present invention provides a semiconductor manufacturing apparatus, which may include a load port, an equipment front end module, a process module, and a load lock module. The load port may load wafers to be handled, and the equipment front end module may be attachable to a wafer handling system and may be adapted to receive wafers to be handled via the load port. The process module may be adapted to process the wafers, and the load lock module may be interposed between the process module and the equipment front end module. The load lock module may further include a chamber, a supply tube, an outlet, and an ejector. The chamber may be adapted to receive at least one wafer, and the supply tube may be adapted to supply purging gas into the chamber. The outlet may be adapted to remove the purging gas from the chamber, and an ejector may be adapted to provide the purging gas, supplied through the supply tube, to the surface of the at least one wafer received by the chamber.

In example embodiments of the present invention, the ejector may include at least one filter positioned on each side of the chamber. In example embodiments of the present invention, the ejector may include at least one filter group positioned on each side of the chamber, and each filter group may include a plurality of filters arranged in parallel. Each filter group may include three filters.

In example embodiments of the present invention, the ejector may include at least one circular filter positioned on each side of the chamber, and which may have the same, or substantially the same, diameter as the wafer.

In example embodiments of the present invention, the ejector may provide the purging gas toward the wafer in at least one of a vertical and a diagonal direction. In example embodiments of the present invention, the purging gas may be an inert gas, for example, nitrogen gas.

In example embodiments of the present invention, the chamber may be adapted to receive a plurality of wafers, and the ejector may include at least one of a plurality of filters and a plurality of filter groups adapted to provide the purging gas to a respective surface of each of the plurality of wafers received by the chamber.

### BRIEF DESCRIPTION OF THE DRAWINGS

The accompanying drawings are included to illustrate example embodiments of the present invention. The drawings, together with the description, explain principles of example embodiments of the present invention. In the drawings:

FIG. 1 is a perspective view illustrating a load lock module, according to an example embodiment of the present invention;

FIG. 2 is a perspective view illustrating a load lock module, according to another example embodiment of the present invention;

FIG. 3 is a perspective view illustrating a load lock module, according to another example embodiments of the present invention;

FIG. 4 is a front view illustrating an example of providing purging gas from a filter in the load lock module, according to another example embodiment of the present invention; and

FIG. 5 is a schematic view illustrating a semiconductor manufacturing apparatus including a load lock module, according to example embodiments of the present invention.

### DETAILED DESCRIPTION OF EXAMPLE EMBODIMENTS OF THE PRESENT INVENTION

Example embodiments of the present invention will be described below in more detail with reference to the accompanying drawings. The present invention may, however, be embodied in different forms and should not be constructed as limited to the example embodiments set forth herein. Example embodiments are provided so that this disclosure will be thorough and complete, and will fully convey the scope of the present invention to those skilled in the art. Like numerals refer to like elements throughout the specification.

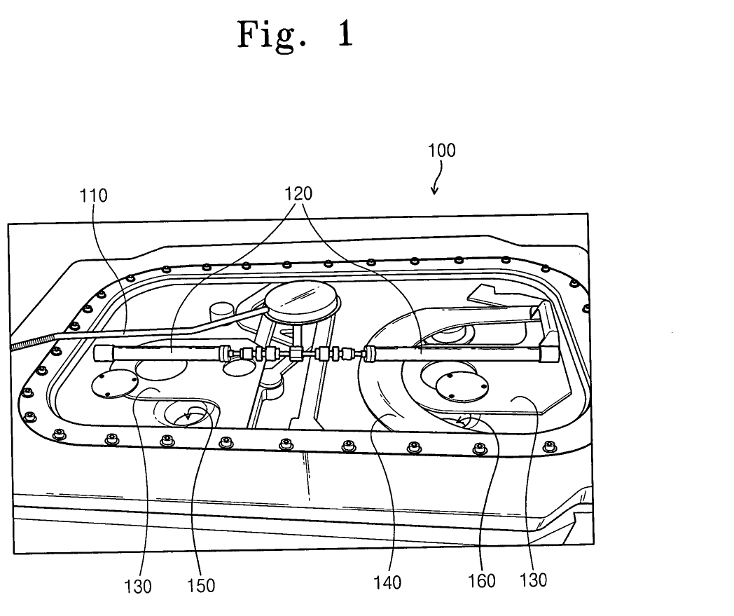

FIG. 1 is a perspective view illustrating a load lock module, according to an example embodiment of the present invention;

Referring to FIG. 1, a load lock module, according to an example embodiment of the present invention may include a chamber 100 in which a buffer 130 and a blade 140, may be installed. Each of the blade 140 and the buffer 130 may be capable of receiving a wafer. A supply tube 110 may supply purging gas into the chamber 100, and an ejector 120 may provide the purging gas to the wafer.

Referring to FIG. 5, the load lock module (LLM) may be interposed between a process module (PM) in which a semiconductor manufacturing process such as etching may be performed, and an equipment front end module (EEFM) to which a wafer handling system may be attached. On a load port (LP), a cassette or front-opening unified pod (FOUP), for example, may be positioned and may include stacked wafers to be processed.

Returning to FIG. 1, an opening 150 may be provided under the chamber 100, and air within the chamber 100 may be removed via the opening 150 by a pump, such that the inside of the chamber 100 may be a vacuum. An additional opening 160 may be provided, for example, under the chamber 100, to remove the purging gas and/or wafer fumes from the chamber 100.

The blade 140 may transfer the wafer from the process module to the chamber 100 of the load lock module, for example, after the wafers have been processed (e.g., etched, etc.). The buffer 130 may be installed at one or both sides of the load lock module and may provide a space for positioning a wafer. The buffer 130 may be operable in, for example, both up and down directions, in order to deliver the wafer to the blade 140 of the load lock module and a blade of the EFEM (not shown).

The purging gas supply tube 110 may be provided to guide the purging gas into the chamber 100 from an external source. The purging gas may be an inert gas such as helium (He), argon (Ar), nitrogen (N₂), or any other suitable inert gas. The purging gas may be used at normal temperatures, or at higher temperatures, for example, when using nitrogen (N₂). When using a higher temperature gas, the inner temperature of the chamber 100 may increase and may assist in diffusing wafer fumes.

The ejector 120 may be a filter and may provide purging gas toward a wafer loaded on the blade 140 and/or the buffer 130, positioned at one or both sides of the load lock module. On the surface of the filter 120, one or more holes or pluralities of holes may be formed to enable the flow purging gas.

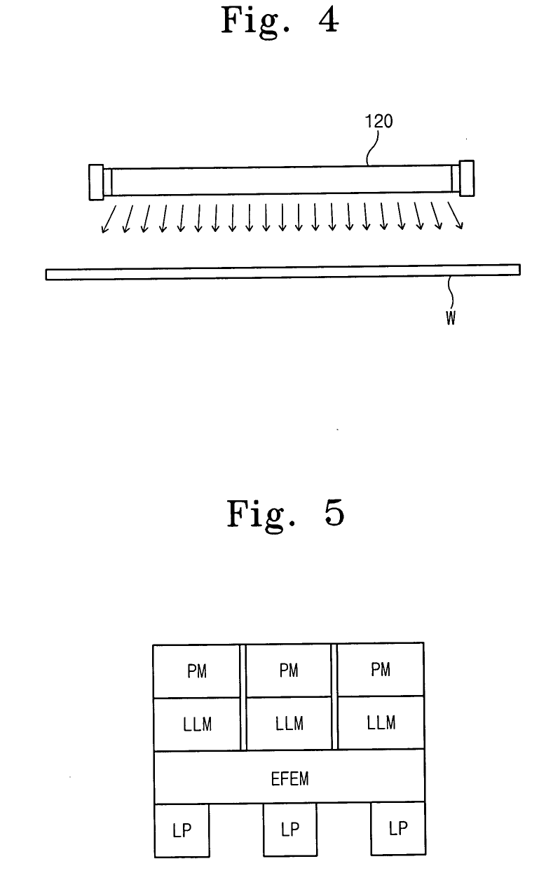

The ejector 120 may provide (e.g., eject) the purging gas, for example, in at least one of a slant direction and a vertical direction as shown, for example, in FIG. 4, in order to cover the wafer, for example, in its entirety. In another example, the purging gas may be provided in a gradually slanted direction, for example, near the end of the ejector 120.

In operation of the load lock module, the blade 140 may take the processed wafer, (e.g., etched wafer), from the process module, and load the wafer on the buffer 130 of the load lock module. The ejector 120 may provide the purging gas toward the wafer mounted on the buffer 130, and wafer fumes sticking to the wafer may be diffused into the chamber 100. For example, as discussed above, higher temperature purging gas may be used to diffuse the wafer fumes and the ejector 120 may provide the purging gas in, for example, a slanted direction, which may provide more uniform distribution over the surface of the wafer. The wafer fumes may be detached from the surface of the wafer, diffused into the chamber 100, and removed out of the chamber 100, for example, through the opening 160.

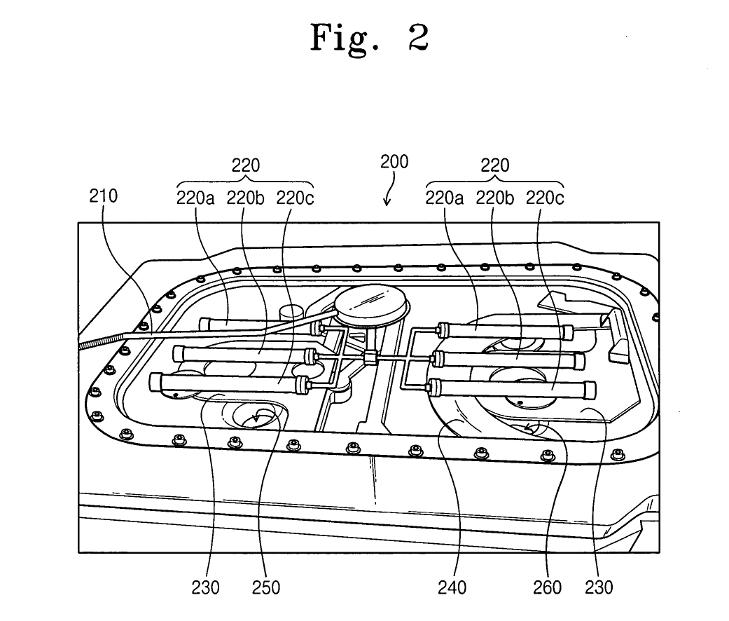

Referring to FIG. 2, the load lock module, according to another example embodiment of the present invention, may include a chamber 200 in which a buffer 230 and a blade 240 may be installed. The load lock module (of FIG. 2) may also include a supply tube 210, which may supply purging gas into the chamber 200, and an ejector 220 having one or more pluralities of filters, 220a, 220b, and 220c, providing purging gas toward the wafer.

The load lock module of FIG. 2 may be the same, or substantially the same, as that of the example embodiment of the present invention as illustrated in FIG. 1; however, the purging gas ejector 220 may include one or more groups of the filters 220a, 220b, and 220c, which may be provided at one or both sides of the load lock module, and may provide uniform, or substantially uniform, distribution of the purging gas over the surface (e.g., entire surface) of the wafer. Each filter group may include a plurality of filters (e.g., three; however, any suitable number may be used) 220a, 220b, and 220c, and may more uniformly distribute the purging gas over the surface of the wafer.

In the example embodiment of the present invention, as illustrated in FIG. 2, the purging gas ejector 220 may provide the purging gas, for example, in a direction diagonal and/or vertical to the wafer, and may accelerate the diffusion of the wafer fumes by using, for example, higher temperature purging gas.

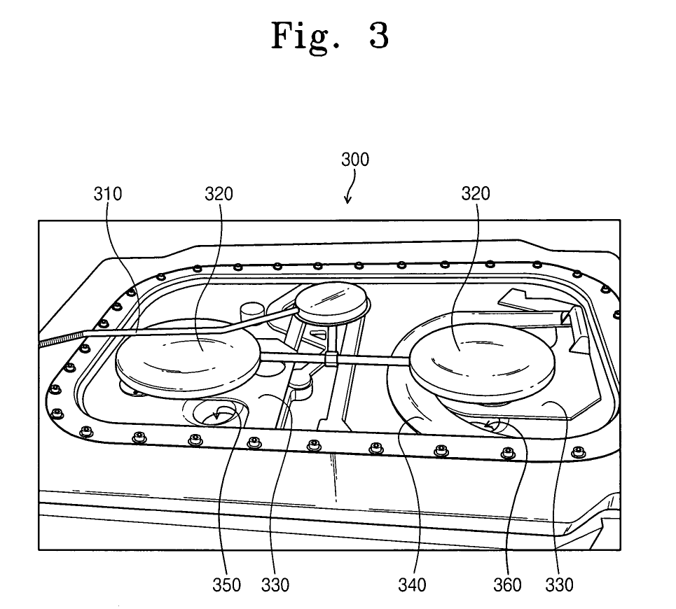

Referring to FIG. 3, the load lock module, according to another example embodiment of the present invention may include a chamber 300 in which a buffer 330 and a blade 340 may be installed. The load lock module (of FIG. 3) may also include a supply tube 310 supplying purging gas into the chamber 300, and an ejector 320. The ejector 320 may have the same, or substantially the same, diameter as the wafer in order to distribute purging gas over the wafer (e.g., the entire wafer).

The load lock module (of FIG. 3) may be the same, or substantially the same, as the example embodiments of the present invention illustrated in FIGS. 1 and/or 2, except for the purging gas ejector 320.

In the example embodiment of the present invention, as illustrated in FIG. 3, the purging gas ejector 320 may include a plurality of circular filters (e.g., two; however, any suitable number may be used) provided at one or more sides (e.g., each side) of the load lock module. Each circular filter, may have the same, or substantially the same, diameter as the wafer, and may more uniformly distribute the purging gas over the wafer.

In the example embodiment of the present invention, as illustrated in FIG. 3, the purging gas ejector 320 may provide the purging gas, for example, in a direction diagonal and/or vertical to the surface of the wafer, and may accelerate the diffusion of the wafer fumes by using, for example, higher temperature purging gas.

Example embodiments of the present invention may removed (e.g., sufficiently remove) wafer fumes from the chamber using a filter (e.g., an improved filter). Example embodiments of the present invention may increase the lifetime and/or reliability of the semiconductor manufacturing apparatus, and/or enhance the cleanness of the front end module.

Although example embodiments of the present invention have been described with regard to FIGS. 1-5, it will be understood that aspects (e.g., ejector structure and/or size, etc.) of each of the FIGS. 1-5 may be interchangeable between example embodiments of the present invention in any suitable manner.

Although example embodiments of the present invention have been described, the present invention is not limited thereto. It will be apparent to those skilled in the art that various substitution, modifications and changes may be thereto without departing from the scope and spirit of the invention.

What is claimed is:

1. A load lock module comprising:
a chamber adapted to receive at least one wafer;
a supply tube adapted to supply purging gas into the chamber;
an outlet adapted to remove the purging gas from the chamber; and
an ejector adapted to provide the purging gas, supplied through the supply tube, to the surface of the at least one wafer received by the chamber.

2. The load lock module as set forth in claim 1, wherein the ejector includes at least one filter positioned on each side of the chamber.

3. The load lock module as set forth in claim 1, wherein the ejector further includes at least one filter group positioned on each side of the chamber.

4. The load lock module as set forth in claim 3, wherein each filter group includes a plurality of filters arranged in parallel.

5. The load lock module as set forth in claim 4, wherein each filter group includes three filters.

6. The load lock module as set forth in claim 1, wherein the ejector includes at least one circular filter positioned on each side of the chamber.

7. The load lock module as set forth in claim 6, wherein the circular filter has the same diameter as the wafer.

8. The load lock module as set forth in claim 1, wherein the ejector provides the purging gas toward the wafer in at least one of a vertical and a diagonal direction.

9. The load lock module as set forth in claim 1, wherein the purging gas is an inert gas.

10. The load lock module as set forth in claim 9, wherein the inert gas is helium, argon, or nitrogen gas.

11. The load lock module as set forth in claim 1, wherein
the chamber is adapted to receive a plurality of wafers, and wherein
the ejector includes at least one of a plurality of filters and a plurality of filter groups adapted to provide the purging gas to a respective surface of each of the plurality of wafers received by the chamber.

12. The load lock module as set forth in claim 11, wherein the purging gas is an inert gas.

13. The load lock module as set forth in claim 12, wherein the inert gas is helium, argon, or nitrogen gas.

14. The load lock module as set forth in claim 11, wherein each filter group has a plurality of filters.

15. The load lock module as set forth in claim 14, wherein the purging gas is an inert gas.

16. The load lock module as set forth in claim 14, wherein the plurality of filters in each filter group are arranged in parallel.

17. The load lock module as set forth in claim 11, wherein the plurality of filters are circular filters.

18. The load lock module as set forth in claim 17, wherein each of the circular filters has the same diameter as at least one of the plurality of wafers.

19. The load lock module as set forth in claim 17, wherein the purging gas is an inert gas.

20. A semiconductor manufacturing apparatus comprising:
a load port for loading wafers to be handled;
an equipment front end module attachable to a wafer handling system and adapted to receive wafers to be handled via the load port;
a process module adapted to process the wafers; and
a load lock module interposed between the process module and the equipment front end module and including,
a chamber adapted to receive at least one processed wafer,
a supply tube adapted to supply purging gas into the chamber,
an outlet adapted to remove the purging gas from the chamber, and
an ejector adapted to provide the purging gas, supplied through the supply tube, to the surface of the at least one processed wafer received by the chamber.
